(19) United States
(12) Patent Application Publication
(10) Pub. No.: US 2014/0318456 A1
(43) Pub. Date: Oct. 30, 2014

(54) HORIZONTAL-TYPE ATOMIC LAYER DEPOSITION APPARATUS FOR LARGE-AREA SUBSTRATES

(71) Applicant: NCD CO., LTD., Daejeon (KR)

(72) Inventors: Woong Chul SHIN, Daejeon (KR); Kyu-Jeong CHOI, Daejeon (KR); Min BAEK, Daejeon (KR)

(73) Assignee: NCD CO., LTD., Daejeon (KR)

(21) Appl. No.: 14/203,956

(22) Filed: Mar. 11, 2014

(30) Foreign Application Priority Data
Apr. 25, 2013 (KR) 10-2013-0046379

(51) Int. Cl. C23C 16/458

(52) U.S. Cl. CPC C23C 16/4583; C23C 16/4585
USPC 118/725; 118/729

(57) ABSTRACT

Disclosed is a horizontal-type atomic layer deposition apparatus for large-area substrates, in which a plurality of large-area substrates can be simultaneously subjected to an atomic layer deposition process in a state in which they are stacked in a horizontal position. The apparatus comprises: an outer chamber that is maintained in a vacuum state; an inner chamber provided in the outer chamber; a chamber cover configured to move upward and downward to open and close the bottom of the inner chamber; a cassette configured to move upward and downward with the chamber cover; a process gas injecting portion configured to inject a process gas into a space between a plurality of substrates loaded in the cassette; a gas discharge portion configured to suck and discharge the process gas; and a substrate introducing/discharging means configured to introduce the substrates into the outer chamber and discharge the substrates.

### BACKGROUND OF THE INVENTION

1. Field of the Invention

The present invention relates to a horizontal-type atomic layer deposition apparatus for large-area substrates, and more particularly to a horizontal-type atomic layer deposition apparatus for large-area substrates, in which a plurality of large-area substrates can be simultaneously subjected to an atomic layer deposition process in a state in which they are stacked in a horizontal position.

2. Description of the Prior Art

Generally, atomic layer deposition processes are widely used to deposit thin layers in precision manufacturing fields, including semiconductor devices, solar cells, OLEDs and the like. In semiconductor manufacturing processes, atomic layer deposition processes are mainly used to deposit thin layers on small-size wafers or the like, and recently, the need to perform atomic layer deposition processes on large-area substrates in manufacturing fields, including solar cells, particularly thin film-type solar cells, and OLEDs, has gradually increased.

In such processes of depositing atomic layers on large-area substrates, the large-area substrates are generally moved in a horizontal direction throughout the entire processes. Thus, the atomic layer deposition process is required to be performed in a state in which the substrate is maintained in a horizontal position in an atomic layer deposition apparatus.

When the large-area substrate is maintained in a horizontal position, the central portion of the substrate is naturally deflected down by gravity, because the thickness of the substrate is thin (for example, 0.3-0.7 cm). Thus, in order to perform the atomic layer deposition process on a large-area substrate in a state in which the substrate is maintained in a horizontal position, a solution for coping with deflection of the large-area substrate is required. In addition, because the time required to perform the atomic layer deposition on a large-area substrate is long, there is an urgent need for the development of technology enabling the atomic layer deposition process to be performed on a plurality of large-area substrates in order to increase the throughput of the atomic layer deposition apparatus.

### SUMMARY OF THE INVENTION

Therefore, it is an object of the present invention to provide a horizontal-type atomic layer deposition apparatus for large-area substrates, in which a plurality of large-area substrates can be simultaneously subjected to an atomic layer deposition process in a state in which the substrates are stacked in a horizontal position.

To achieve the above object, the present invention provides a horizontal-type atomic layer deposition apparatus comprising: an outer chamber that is maintained in a vacuum state; an inner chamber provided in the outer chamber and having a rectangular box shape that is open at the bottom; a chamber cover provided beneath the inner chamber and configured to move upward and downward to open and close the bottom of the inner chamber; a cassette which is provided on the chamber cover and configured to move upward and downward with the chamber cover and in which a plurality of substrates are loaded in a horizontal position so as to be spaced from each other at a distance corresponding to laminar flow; a process gas injecting portion provided at one side wall of the inner chamber and configured to inject a process gas into a space between the plurality of substrates loaded in the cassette; a gas discharge portion provided at a side wall of the inner chamber, which faces the one side wall at which the process gas injecting portion is provided, the gas discharge portion being configured to suck and discharge the process gas injected into the process gas injecting portion; and a substrate introducing/discharging means configured to introduce the large-area substrates into the outer chamber and discharge the large-area substrates from the outer chamber.

In the present invention, the cassette preferably comprises: a plurality of substrate support panels configured to support the lower surface of the substrates, introduced into the outer chamber by the substrate introducing/discharging means, so as not to deflect; a cassette rod coupled to each corner of the substrate support panels and stood up on each corner of the chamber cover; and a panel moving means provided around the cassette rod and configured to independently move the plurality of substrate support panels upward and downward.

The substrate introducing/discharging means preferably comprises a plurality of rotating rollers arranged in parallel in a horizontal direction and configured to rotate to move the large-area substrates in a horizontal direction while supporting the lower side of both edges of the large-area substrates.

The substrate support panels preferably have roller passage grooves formed at the edge thereof in order to avoid interference with the rotating rollers during upward and downward movement.

The substrate introducing/discharging means preferably further comprises a roller moving means configured to move the rotating rollers outward from the central portion of the outer chamber to control the distance between the rotating rollers.

The horizontal-type atomic layer deposition apparatus according to the present invention preferably further comprises a sealing member configured to seal between the inner chamber and the chamber cover.

The horizontal-type atomic layer deposition apparatus according to the present invention preferably further comprises a heating unit in the outer chamber or the inner chamber.

### BRIEF DESCRIPTION OF THE DRAWINGS

FIG. 1 shows the configuration of a horizontal-type atomic layer deposition apparatus according to an embodiment of the present invention.

FIG. 2 is a view in another direction, which shows the configuration of a horizontal-type atomic layer deposition apparatus according to an embodiment of the present invention.

FIG. 3 is a sectional view showing a substrate placed securely on a substrate support panel according to an embodiment of the present invention.

FIG. 4 is a perspective view showing the structure of a substrate support panel according to an embodiment of the present invention.

FIGS. 5a and 5b show a process in which a substrate is placed securely on a substrate support panel according to an embodiment of the present invention.

FIG. 6 shows the structure of a cassette according to an embodiment of the present invention.

FIG. 7 shows a process in which an atomic layer deposition process is performed in a horizontal-type atomic layer deposition apparatus according to an embodiment of the present invention.

FIG. 8 shows the structure of a roller passage groove-filling portion according to an embodiment of the present invention.

### DETAILED DESCRIPTION OF THE INVENTION

Hereinafter, preferred embodiments of the present invention will be described in detail with reference to the accompanying drawings.

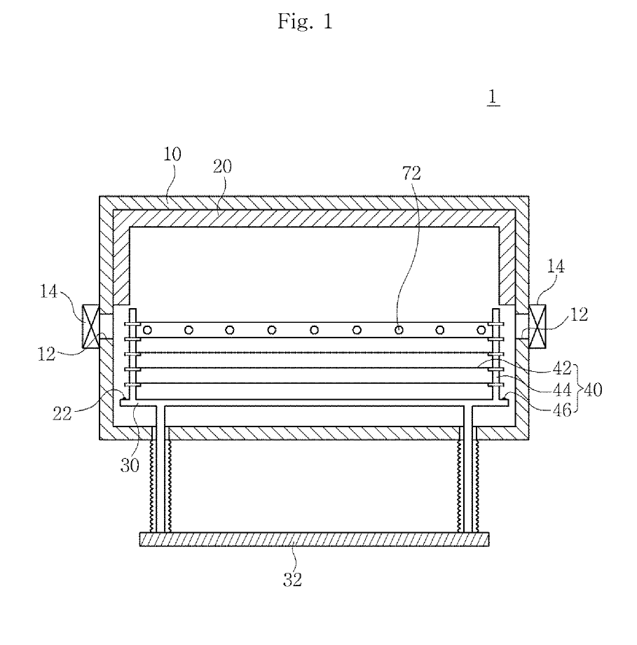

As shown in FIG. 1, a horizontal-type atomic layer deposition apparatus 1 according to an embodiment of the present invention comprises an outer chamber 10, an inner chamber 20, a chamber cover 30, a cassette 40, a process gas injecting portion 50, a gas discharge portion 60 and a substrate introducing/discharging means 70.

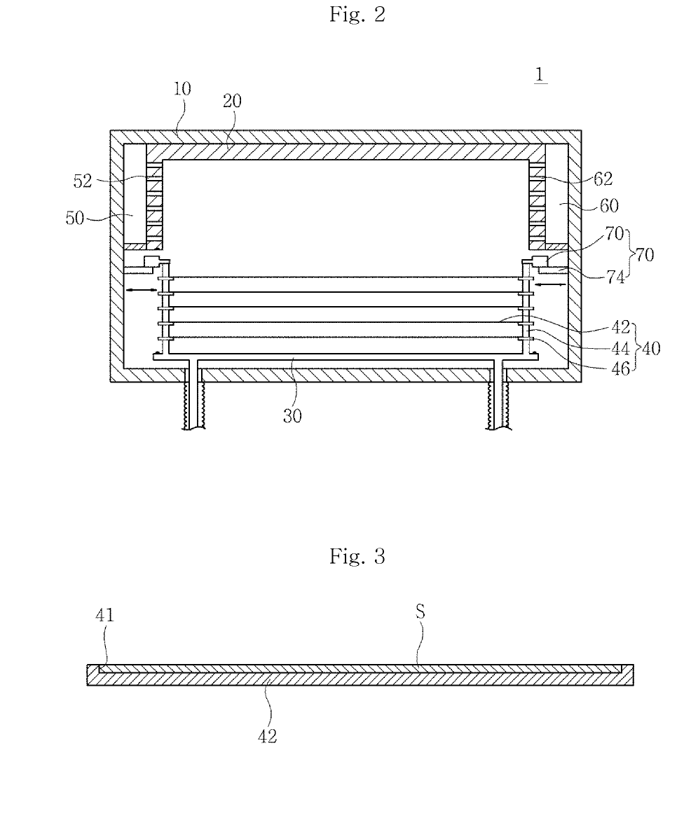

As shown in FIGS. 1 and 2, the outer chamber 10 constitutes the external shape of the horizontal-type atomic layer deposition apparatus according to this embodiment and may have a rectangular parallelepiped shape having a closed space formed therein. In the outer chamber 10, a high-performance vacuum pump (not shown) capable of sucking and discharging gas from the chamber to the outside is provided.

As shown in FIG. 1, a gate 12 through which substrates S can pass is formed in one side wall of the outer chamber 10, and a gate valve capable of controlling the gate 12 is provided in the gate 12. In addition, the gate 12 is also formed in the other side wall of the outer chamber 10 so that the atomic layer deposition process can be performed while the substrates move in a constant direction.

Moreover, a load lock chamber (not shown) may further be provided at the side of the outer chamber 10, which has the gate 12 formed therein. The load lock chamber can serve to receive the substrates to be introduced into the outer chamber 10 and preheat and depressurize the substrates to a vacuum state so as to enable the substrates to be introduced into the outer chamber 10 without breaking the vacuum of the outer chamber 10. Alternatively, the load lock chamber can serve to receive the substrates from the outer chamber 10 in a vacuum state in order to reduce the process time.

As shown in FIGS. 1 and 2, the inner chamber 20 is disposed in the upper portion of the outer chamber 10 and has a rectangular box shape that is open at the bottom. The atomic layer deposition process is actually performed in the inner chamber 20. In the horizontal-type atomic layer deposition apparatus 1 according to this embodiment, a combination of the inner chamber 20 and a cassette 40 as described below is provided so that a space into which a process gas is introduced can be minimized while the atomic layer deposition process can be performed in a state in which a plurality of large-area substrates are stacked, that is, a batch manner.

Meanwhile, as shown in FIGS. 1, 2 and 7, the chamber cover 30 is provided at the bottom of the inner chamber 20 and configured to move upward and downward so as to open/close the open bottom of the inner chamber 20. In other words, the inner chamber 20 is combined with the chamber cover 30 to form a closed space in which the atomic layer deposition process is performed. In addition, a sealing member 22 may further be provided at the contact between the inner chamber 20 and the chamber cover 30 in order to maintain the sealing of the closed space.

Further, a cover moving means 32 capable of moving the chamber cover 30 upward and downward is provided beneath the chamber cover 30.

As shown in FIGS. 1 and 2, the cassette 40 is an element which is disposed on the chamber cover 30 and configured to move upward and downward with the chamber cover 30 and in which a plurality of large-area substrates are loaded horizontally in parallel with each other at a distance corresponding to laminar flow (hereinafter referred to as “laminar flow distance”).

In other words, as shown in FIG. 6, the cassette 40 is composed of a support panel 42, a cassette rod 44 and a panel moving means 46 in order to support the plurality of large-area substrates at the laminar flow distance without deflection.

The substrate support panel 42 is configured to support the lower surface of the substrates S, introduced into the outer chamber 10 by the substrate introducing/discharging means 70, so as not to deflect. As shown in FIG. 6, a plurality of substrate support panels 42 are provided in parallel in one cassette 40.

Each of the substrate support panels 42 is made of a large-area material that has strength enough to prevent the central portion thereof from deflecting downward. Because the large-area substrates 42 are subjected to the atomic layer deposition process in a state in which they are placed on the substrate support panels 42, the surface of the substrate support panels 42 may be coated with a special material in order to prevent contamination and particle generation in the atomic layer deposition process. For example, the surface of the substrate support panels 42 may be coated with the same material as a material to be deposited in the atomic layer deposition process.

In this embodiment, the substrate support panels 42 generally have a rectangular panel shape, and as shown in FIG. 3, a substrate receiving groove 41 is formed on each of the substrate support panels 42 such that only the upper surface of the substrates S can be exposed in a state in which the substrate is received in the substrate receiving groove 41.

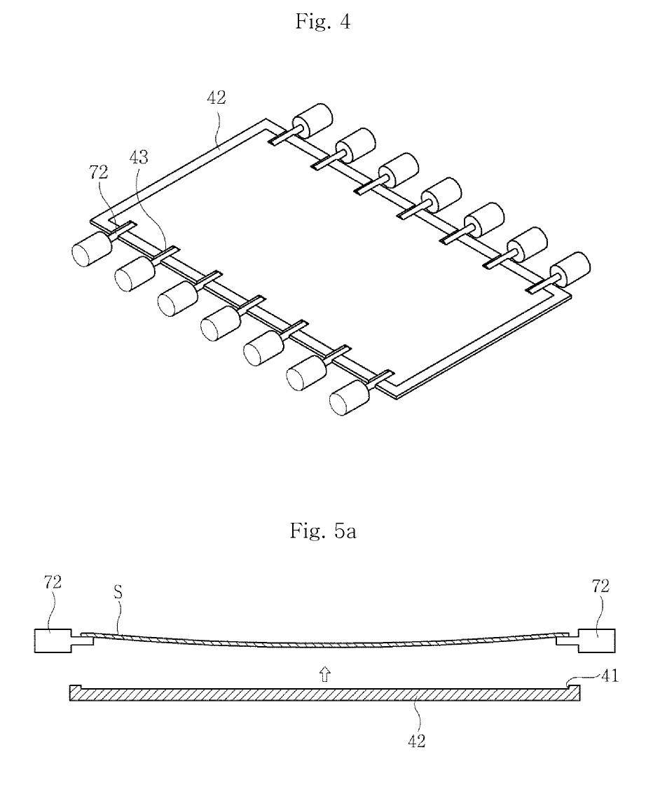

As shown in FIG. 4, a plurality of roller passage grooves 43 are formed at the left and right edges of the substrate support panel 42. The plurality of roller passage grooves 43 are formed at the same distance as that between a plurality of rotating rollers 72 that constitute the substrate introducing/discharging means 70. The roller passage groves 43 have a sufficient size such that the rotating rollers 72 can pass therethrough.

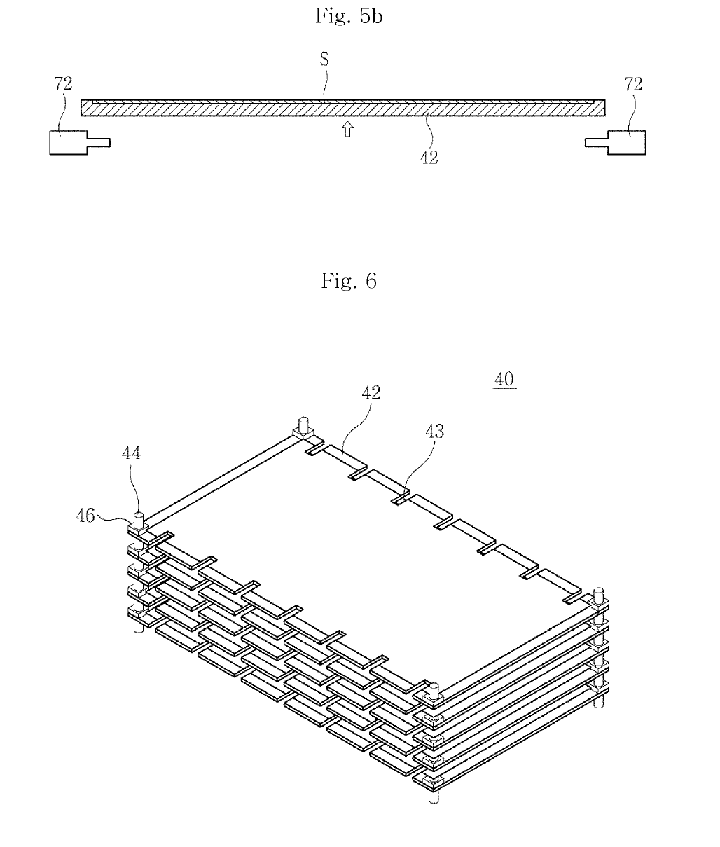

As shown in FIG. 5, the rotating rollers 72 that support the substrate S can move upward through the roller passage grooves 43, and thus the substrate S can be elevated without collision with the rotating rollers 72.

As shown in FIG. 6, the cassette rod 44 is combined with each corner of the substrate support panels 42 and stood up on each corner of the chamber cover 30. In other words, the cassette rod 44 functions to provide a position for placing the substrate support panels 42 and to provide a path through which the substrate support panels 42 can be accurately moved upward and downward by the panel moving means 46.

As shown in FIG. 6, a plurality of panel moving means 46 are provided around the cassette rod 44 and configured to independently move the plurality of substrate support panels 42 upward and downward. In this embodiment, the plurality of substrate support panels 42 may have various distances in a state in which they do not support the substrates S, but should be maintained at the laminar flow distance so that the atomic layer deposition process can be performed, in a state in which these support panels 42 support the substrates S. Thus, the panel moving means 46 serve to independently move the substrate support panels 42 while they move along the cassette rod 44. Herein, the panel moving means 46 serve to control the distance between the substrate support panels 42 to a distance equal to or smaller than a predetermined laminar flow distance.

In this embodiment, the panel moving means 46 are provided around the cassette rods 44, respectively, so as to serve to independently move the four corners of the substrate support panels 42 upward and downward, but the substrate support panels 42 are controlled such that they are arranged horizontally with respect to the ground.

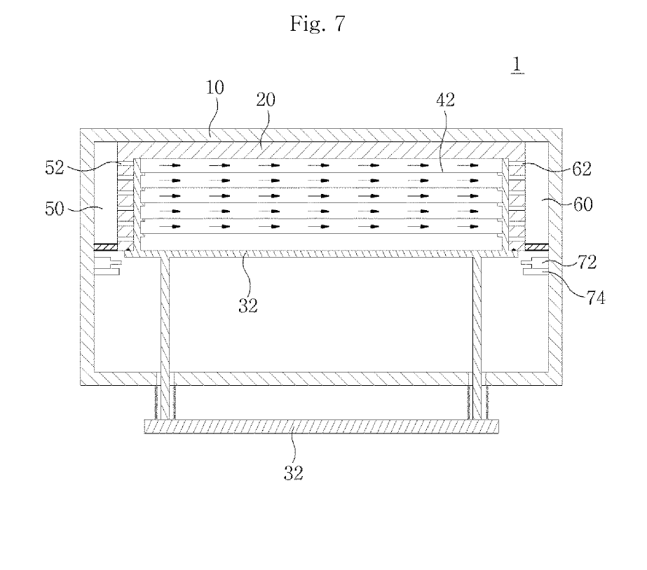

As shown in FIGS. 1 and 7, a process gas injecting portion 50 is provided at one side wall of the inner chamber 20 and configured to inject a process gas into the space between the plurality of substrate support panels 42 mounted in the cassette 40. The process gas injecting portion 50 is configured to receive the process gas from a supply gas supply source (not shown) provided outside the outer chamber. The process gas that is injected by the process gas injecting portion 50 is uniformly injected through injection holes 52. Herein, the process gas for use in the atomic layer deposition process is supplied in a pulse form.

As shown in FIGS. 2 and 7, a gas discharge portion 60 is provided at the side wall of the inner chamber 20, which faces the side wall at which the process gas injecting portion 50 is provided. The gas discharge portion 60 is configured to suck and discharge the process gas injected from the process gas injecting portion 50. The gas discharge portion 60 is formed to communicate with gas discharge holes and configured to completely suck and discharge the process gas, injected from the process gas injecting portion 50, to the outside.

As shown in FIGS. 1 and 2, the substrate introducing/discharging means 70 is configured to introduce the large-area substrates S into the outer chamber 10 and discharge the substrates from the outer chamber 10. The substrate introducing/discharging means 70 has various structures that can horizontally move the large-area substrates. Specifically, in this embodiment, the substrate introducing/discharging means 70 may be composed of a plurality of rotating rollers 72, which are arranged horizontally in parallel and configured to rotate to move the large-area substrates in a horizontal direction while supporting the lower side of both edges of the large-area substrates.

In other words, the rotating rollers 72 are configured to rotate while supporting both edges of the large-area substrates S, thereby moving the large-area substrates S either into the outer chamber 10 or from the inside to the outside of the outer chamber 10. Meanwhile, in order to avoid interference in the process in which the chamber cover 30 moves upward so as to be combined with the inner chamber 20, the rotating rollers 72 in the horizontal-type atomic layer deposition apparatus 1 according to this embodiment are required to move outward in a horizontal direction as shown in FIG. 7.

Thus, in this embodiment, the substrate introducing/charging means 70 preferably further comprises a roller moving means 74 configured to horizontally move the rotating rollers 72 outward from the central region of the outer chamber 10 to control the distance between the rotating rollers 72 that face each other.

In the process in which each of the large-area substrates S is moved horizontally moved by the roller moving means 74 and mounted on or separated from the substrate support panel 42, the distance between a pair of the rotating rollers 72 is controlled to be reduced, and in the process in which the chamber cover 30 moves upward or downward, the distance between a pair of the rotating rollers 72 is controlled to be increased so that the rotating rollers 72 do not interfere with the vertical movement of the chamber cover 30.

Meanwhile, in the horizontal-type atomic layer deposition apparatus 1 according to this embodiment, a heating unit (not shown) may be provided in the outer chamber 10 or the inner chamber 20. In other words, the heating unit is configured to heat the substrates to a required process temperature, for example, a temperature of 100˜150° C. in order to facilitate the atomic layer deposition process.

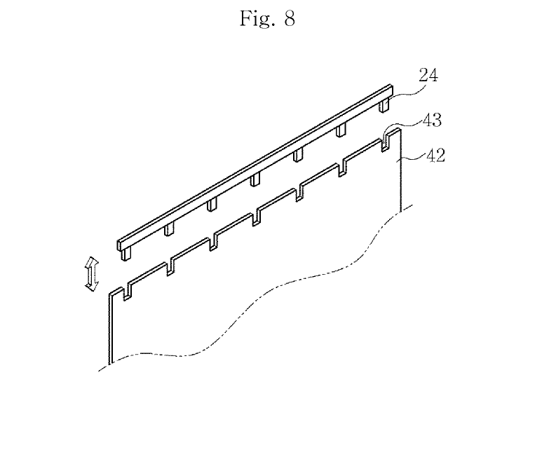

In addition, as shown in FIG. 8, the inner chamber 20 in the horizontal-type atomic layer deposition apparatus 1 according to the present invention may further comprise a passage groove-filling portion 24 capable of filling the roller passage grooves 43 formed on the substrate support panels 42. The passage groove-filling portion 24 is provided on the side wall of the inner chamber 20 in such a manner that it can move horizontally forward and backward. After the substrate support panels 42 were completely introduced into the inner chamber 20, the passage groove-filling portion 24 moves forward and is inserted into the roller passage grooves 43 to completely fill the roller passage grooves 43. This filling is performed so that the curved portion of the roller passage grooves 43 formed on the substrate support panels 42 does not interfere with the laminar flow of the process gas.

Hereinafter, an atomic layer deposition process that is performed using the horizontal-type atomic layer deposition apparatus 1 according to this embodiment will be described.

First, substrates are introduced into the outer chamber 10. At this time, as shown in FIG. 2, the process of producing the substrates is performed while the distance between a pair of the rotating rollers 72 is controlled to be reduced.

The process of introducing the substrates is performed in a state in which the gate valve 14 is opened. At this time, the chamber cover 30 is in a state in which it moved downward, and the substrates S are loaded on the substrate support panels 42, starting from the uppermost substrate support panel 42. As one substrate S is loaded, the chamber cover 30 moves upward by one pitch, and after the substrates were loaded on all the substrate support panels 42, the process of introducing the substrates is completed, and the gate valve 14 is closed. Also, the roller moving means 74 is driven to increase the distance between the rotating rollers 72, so that the rotating rollers 72 do not interfere with the upward movement of the chamber cover 30.

Furthermore, the distance between the substrate support panels 42 is controlled by the panel moving means 46 so that the distance between the substrate support panels 42 is maintained at the laminar flow distance.

At the same time, the chamber cover 30 moves upward, and thus as shown in FIG. 7, the chamber 30 adheres closely to the inner chamber 20, and the internal space of the inner chamber is closed. In this state, an atomic layer deposition process is performed while a process gas is injected from the process gas injecting portion 50 and sucked in the gas discharge portion 60. This deposition process is repeated until a required deposition thickness is reached.

After completion of the deposition process, the chamber cover 30 is moved downward as shown in FIG. 2. As the chamber cover 30 is gradually moved downward, the distance between the rotating rollers 72 becomes narrower, and the substrates S loaded on the substrate support panels 42 are discharged to the outside by the rotating rollers 72, starting from the substrate S loaded on the lowest substrate support panel 42. Herein, the substrates may be discharged through either the gate used to introduce the substrates or the opposite gate.

As described above, according to the present invention, a plurality of large-area substrates can be simultaneously subjected to an atomic layer deposition process in a state in they are maintained in a horizontal position in the same manner as a state in which the substrates are moved in a transfer line. Thus, the present invention has an advantage in that the throughput of the deposition process is high.

In addition, deflection of large-area substrates can be completely prevented to minimize the distance between the substrates, thereby greatly reducing the consumption of process gas that is used in the deposition process and shortening the process time.

Additionally, the atomic layer deposition apparatus according to the present invention enables to construct an in-line layout that can perform the deposition process while moving large-area substrates in a constant direction.

What is claimed is:

1. A horizontal-type atomic layer deposition apparatus comprising:
an outer chamber that is maintained in a vacuum state;
an inner chamber provided in the outer chamber and having a rectangular box shape that is open at the bottom;
a chamber cover provided beneath the inner chamber and configured to move upward and downward to open and close the bottom of the inner chamber;
a cassette which is provided on the chamber cover and configured to move upward and downward with the chamber cover and in which a plurality of substrates are loaded in a horizontal position so as to be spaced from each other at a distance corresponding to laminar flow;
a process gas injecting portion provided at one side wall of the inner chamber and configured to inject a process gas into a space between the plurality of substrates loaded in the cassette;
a gas discharge portion provided at a side wall of the inner chamber, which faces the one side wall at which the process gas injecting portion is provided, the gas discharge portion being configured to suck and discharge the process gas injected into the process gas injecting portion; and
a substrate introducing/discharging means configured to introduce the large-area substrates into the outer chamber and discharge the large-area substrates from the outer chamber.

2. The horizontal-type atomic layer deposition apparatus of claim 1, wherein the cassette comprises:
a plurality of substrate support panels configured to support the lower surface of the substrates, introduced into the outer chamber by the substrate introducing/discharging means, so as not to deflect;
a cassette rod coupled to each corner of the substrate support panels and stood up on each corner of the chamber cover; and
a panel moving means provided around the cassette rod and configured to independently move the plurality of substrate support panels upward and downward.

3. The horizontal-type atomic layer deposition apparatus of claim 2, wherein the substrate introducing/discharging means preferably comprises a plurality of rotating rollers arranged in parallel in a horizontal direction and configured to rotate to move the large-area substrates in a horizontal direction while supporting the lower side of both edges of the large-area substrates.

4. The horizontal-type atomic layer deposition apparatus of claim 3, wherein the substrate support panels have roller passage grooves formed at the edge thereof in order to avoid interference with the rotating rollers during upward and downward movement.

5. The horizontal-type atomic layer deposition apparatus of claim 3, wherein the substrate introducing/discharging means further comprises a roller moving means configured to move the rotating rollers outward from the central portion of the outer chamber to control the distance between the rotating rollers.

6. The horizontal-type atomic layer deposition apparatus of claim 1, further comprising a sealing member configured to seal between the inner chamber and the chamber cover.

7. The horizontal-type atomic layer deposition apparatus of claim 1, further comprising a heating unit in the outer chamber or the inner chamber.
